(19) United States
(12) Patent Application Publication
(10) Pub. No.: US 2006/0226117 A1
(43) Pub. Date: Oct. 12, 2006

(54) Phase change based heating element system and method

(76) Inventors: Ronald T. Bertram, Gilbert, AZ (US); Joseph T. Hillman, Scottsdale, AZ (US); Maximilan A. Biberger, Scottsdale, AZ (US)

Correspondence Address: HAVERSTOCK & OWENS LLP, 162 NORTH WOLFE ROAD, SUNNYVALE, CA, 94086, US

(21) Appl. No.: 11/093,536

(22) Filed: Mar. 29, 2005

(51) Int. Cl. C03C 25/68; G01L 21/30; H01L 21/306

(52) U.S. Cl. 216/59; 216/58; 156/345.25

(57) ABSTRACT

A method of and apparatus for regulating carbon dioxide using a pre-injection assembly coupled to a processing chamber operating at a supercritical state is disclosed. The method and apparatus utilize a source for providing supercritical carbon dioxide to the pre-injection assembly and a temperature control element for maintaining the pre-injection region at a supercritical temperature and pressure.

### FIELD OF THE INVENTION

This invention relates to the field of particle prevention techniques in cleaning silicon wafers. More particularly, the present invention relates to the field of reducing substrate material contaminants during supercritical carbon dioxide processes.

### BACKGROUND OF THE INVENTION

Carbon Dioxide (CO₂) is an environmentally friendly, naturally abundant, non-polar molecule. Being non-polar, CO₂ has the capacity to dissolve in and dissolve a variety of non-polar materials or contaminates. The degree to which the contaminants found in non-polar CO₂ are soluble is dependant on the physical state of the CO₂. The four phases of CO₂ are solid, liquid, gas, and supercritical. These states are differentiated by appropriate combinations of specific pressures and temperatures. CO₂ in a supercritical state (sc-CO₂) is neither liquid nor gas but embodies properties of both. In addition, sc-CO₂ lacks any meaningful surface tension while interacting with solid surfaces, and hence, can readily penetrate high aspect ratio geometrical features more readily than liquid CO₂. Moreover, because of its low viscosity and liquid-like characteristics, the sc-CO₂ can easily dissolve large quantities of many other chemicals. It has been shown that as the temperature and pressure are increased into the supercritical phase, the solubility of CO₂ also increases. This increase in solubility has lead to the development of sc-CO₂ cleaning, extractions, and degreasing.

Supercritical fluids have been used to remove residue from surfaces or extract contaminants from various materials. For example, as described in U.S. Pat. No. 6,367,491 to Marshall, et al., entitled “Apparatus for Contaminant Removal Using Natural Convection Flow and Changes in Solubility Concentration by Temperature,” issued Apr. 9, 2002, supercritical and near-supercritical fluids have been used as solvents to clean contaminants from articles; citing, NASA Tech Brief MFS-29611 (December 1990), describing the use of supercritical carbon dioxide as an alternative for hydrocarbon solvents conventionally used for washing organic and inorganic contaminants from the surfaces of metal parts.

Supercritical fluids have been employed in the cleaning of semiconductor wafers. For example, an approach to using supercritical carbon dioxide to remove exposed organic photoresist film is disclosed in U.S. Pat. No. 4,944,837 to Nishikawa, et al., entitled “Method of Processing an Article in a Supercritical Atmosphere,” issued Jul. 31, 1990.

When cleaning semiconductor wafers with supercritical fluids it is important that contamination and particles be minimized by maintaining the proper temperatures and pressures to eliminate phase changes during processing. Cold spots in the system can allow contaminants to fall out, the fluid to change its phase, or both.

What is needed is a method of and system for preventing phase changes from occurring in high-pressure semiconductor processing systems.

### SUMMARY OF THE INVENTION

In accordance with the present invention, a method of and apparatus for pre-processing carbon dioxide using a pre-injection assembly coupled to a processing chamber operating at a supercritical state is disclosed. The supercritical state is defined by both a temperature and a pressure. The method comprises the steps of providing supercritical carbon dioxide to a preinjection region within the pre-injection assembly; isolating the preinjection region; and maintaining the preinjection region at a supercritical temperature and pressure.

The supercritical temperature and pressure of the preinjection region is maintained by adding a heating element to the assembly. The heating element can comprise a heater blanket and/or heat tape. Preferably, the heat element includes temperature controllers or built-in preset thermostats to prevent overheating. The pre-injection assembly can comprise a discharge means for discharging particles from the preinjection region.

### BRIEF DESCRIPTION OF THE DRAWINGS

A more complete appreciation of various embodiments of the invention and many of the attendant advantages thereof will become readily apparent with reference to the following detailed description, particularly when considered in conjunction with the accompanying drawings, in which:

FIG. 1 shows an exemplary block diagram of a processing system in accordance with embodiments of the invention;

FIG. 2 illustrates a simplified block diagram of a pre-injection assembly in accordance with an embodiment of the invention;

FIG. 3 illustrates an exemplary graph of pressure versus time for supercritical processes in accordance with an embodiment of the invention; and

FIG. 4 illustrates a flow diagram of a method for operating a pre-injection assembly in accordance with an embodiment of the invention.

### DETAILED DESCRIPTION OF SEVERAL EMBODIMENTS

Embodiments of the present invention disclose a pre-injection assembly that enables the injection of a temperature-controlled high-pressure processing fluid/solution into a closed loop environment. The closed loop environment is preferably under high pressure. In one embodiment, the high-pressure system can exceed 3,000 psi.

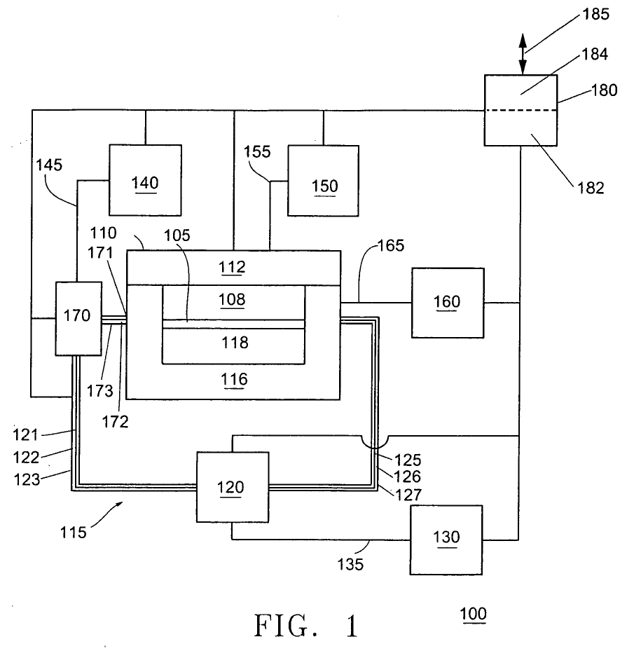

FIG. 1 shows an exemplary block diagram of a processing system in accordance with an embodiment of the invention. In the illustrated embodiment, processing system 100 comprises a process module 110, a recirculation system 120, a process chemistry supply system 130, a high-pressure fluid supply system 140, an exhaust control system 150, a pressure control system 160, a pre-injection assembly 170, and a controller 180. The processing system 100 can operate at pressures that can range from 1000 psi. to 10,000 psi. In addition, the processing system 100 can operate at temperatures that can range from 40 to 300 degrees Celsius.

The details concerning one example of a processing chamber are disclosed in co-owned and co-pending U.S. patent application Ser. No. 09/912,844, entitled “HIGH PRESSURE PROCESSING CHAMBER FOR SEMICONDUCTOR SUBSTRATE,” filed Jul. 24, 2001, Ser. No. 09/970,309, entitled “HIGH PRESSURE PROCESSING CHAMBER FOR MULTIPLE SEMICONDUCTOR SUBSTRATES,” filed Oct. 3, 2001, Ser. No. 10/121,791, entitled “HIGH PRESSURE PROCESSING CHAMBER FOR SEMICONDUCTOR SUBSTRATE INCLUDING FLOW ENHANCING FEATURES,” filed Apr. 10, 2002, and Ser. No. 10/364,284, entitled “HIGH-PRESSURE PROCESSING CHAMBER FOR A SEMICONDUCTOR WAFER,” filed Feb. 10, 2003, the contents of which are incorporated herein by reference.

The controller 180 can be coupled to the process module 110, the recirculation system 120, the process chemistry supply system 130, the high-pressure fluid supply system 140, the exhaust control system 150, the pressure control system 160, and the pre-injection assembly 170. Alternately, controller 180 can be coupled to one or more additional controllers/computers (not shown), and controller 180 can obtain setup, configuration, and/or recipe information from an additional controller/computer.

In FIG. 1, singular processing elements (110, 120, 130, 140, 150, 160, 170, and 180) are shown, but this is not required for the invention. The semiconductor processing system 100 can comprise any number of processing elements having any number of controllers associated with them in addition to independent processing elements.

The controller 180 can be used to configure any number of processing elements (110, 120, 130, 140, 150, 160, and 170), and the controller 180 can collect, provide, process, store, and display data from processing elements. The controller 180 can comprise a number of applications for controlling one or more of the processing elements. For example, controller 180 can include a GUI component (not shown) that can provide easy to use interfaces that enable a user to monitor and/or control one or more processing elements.

The process module 110 can include an upper assembly 112 and a lower assembly 116, and the upper assembly 112 can be coupled to the lower assembly 116. In an alternate embodiment, a frame and or injection ring can be included and can be coupled to an upper assembly and a lower assembly. The upper assembly 112 can comprise a heater (not shown) for heating the process chamber, the substrate, or the processing fluid, or a combination of two or more thereof. Alternately, a heater is not required in the upper assembly 112. In another embodiment, the lower assembly 116 can comprise a heater (not shown) for heating the process chamber, the substrate, or the processing fluid, or a combination of two or more thereof. The process module 110 can include means for flowing a processing fluid through the processing chamber 108. In one example, a circular flow pattern can be established, and in another example, a substantially linear flow pattern can be established. Alternately, the means for flowing can be configured differently. The lower assembly 116 can comprise one or more lifters (not shown) for moving the chuck 118 and/or the substrate 105. Alternately, a lifter is not required.

In one embodiment, the process module 110 can include a holder or chuck 118 for supporting and holding the substrate 105 while processing the substrate 105. The holder or chuck 118 can also be configured to heat or cool the substrate 105 before, during, and/or after processing the substrate 105. Alternately, the process module 110 can include a platen for supporting and holding the substrate 105 while processing the substrate 105.

A transfer system (not shown) can be used to move a substrate into and out of the processing chamber 108 through a slot (not shown). In one example, the slot can be opened and closed by moving the chuck, and in another example, the slot can be controlled using a gate valve.

The substrate can include semiconductor material, metallic material, dielectric material, ceramic material, or polymer material, or a combination of two or more thereof. The semiconductor material can include Si, Ge, Si/Ge, or GaAs. The metallic material can include Cu, Al, Ni, Pb, Ti, Ta, or W, or combinations of two or more thereof. The dielectric material can include Si, O, N, H, P, or C, or combinations of two or more thereof. The ceramic material can include Al, N, Si, C, or O, or combinations of two or more thereof.

In one embodiment, processing system 100 can further comprise temperature controlled process tubing (121, 125 and 171) for coupling the process module 110 to the recirculation system 120, and a recirculation loop 115 can be configured that includes a portion of the recirculation system, a portion of the process module 110, temperature controlled process tubing 121, and temperature controlled process tubing 125. In addition, the temperature-controlled process tubing (121, 125, and 171) can operate at temperatures that can range from 40 to 300 degrees Celsius and pressures that can range from 1000 psi. to 10,000 psi.

In alternate embodiments, temperature controlled process tubing may not be required. In one embodiment, the recirculation loop 115 comprises a volume of approximately one liter. In alternate embodiments, the volume of the recirculation loop 115 can vary from approximately 0.5 liters to approximately 2.5 liters.

In addition, processing system 100 can comprise temperature-controlled process tubing 171 coupling the pre-injection assembly 170 to the process module 110. In alternate embodiments, temperature controlled process tubing may not be required. In addition, the controller can be coupled to and used to control the temperature-controlled process tubing 171. The pre-injection assembly 170 can comprise means (not shown) for providing temperature-controlled fluid to the processing chamber 108. Alternately, the pre-injection assembly 170 can comprise means (not shown) for providing temperature-controlled fluid to one or more elements in the recirculation loop 115. For example, the pre-injection assembly 170 can comprise means (not shown) for providing temperature-controlled CO₂.

The temperature-controlled process tubing (121, 125, and/or 171) can comprise a heater (122, 126, and 172) that can cover a substantial portion (approximately ninety percent) of the outside surface area of the process tubing. For example, the heater can include a high temperature tape heater, such as Thermolyne® silicone rubber-encapsulated heating tape from Sigma Aldrich. In addition, the temperature-controlled process tubing (121, 125, and/or 171) can comprise an insulation layer (123, 127, and 173) that can cover a substantial portion (approximately ninety percent) of the outside surface area of the heater. For example, the insulation layer can include a high temperature insulation material, such as silicone foam from Quantum Silicones. The heater and insulation layer can be configured using one or more pieces that can be easily replaced during a maintenance operation.

Furthermore, the controller 180 can be coupled to and used to control the temperature-controlled process tubing 121, the temperature-controlled process tubing 125, and/or the temperature-controlled process tubing 171.

The pre-injection assembly 170 can operate at temperatures that can range from 40 to 300 degrees Celsius and pressures that can range from 1000 psi. to 10,000 psi. The flow rate from pre-injection assembly 170 can vary from approximately 0.01 liters/minute to approximately 100 liters/minute.

The recirculation system 120 can comprise one or more pumps (not shown) that can be used to regulate the flow of the supercritical processing solution through the processing chamber 108 and the other elements in the recirculation loop 115. The flow rate can vary from approximately 0.01 liters/minute to approximately 100 liters/minute.

The recirculation system 120 can comprise one or more valves (not shown) for regulating the flow of a supercritical processing solution through the recirculation loop 115. For example, the recirculation system 120 can comprise any number of back-flow valves, filters, pumps, and/or heaters (not shown) for maintaining a supercritical processing solution and flowing the supercritical process solution through the recirculation system 120 and through the processing chamber 108 in the process module 110.

Processing system 100 can comprise a process chemistry supply system 130. In the illustrated embodiment, the process chemistry supply system is coupled to the recirculation system 120 using one or more lines 135, but this is not required for the invention. In alternate embodiments, the process chemistry supply system can be configured differently and can be coupled to different elements in the processing system.

The process chemistry is introduced by the process chemistry supply system 130 into the fluid introduced by the high-pressure fluid supply system 140 at ratios that vary with the substrate properties, the chemistry being used, and the process being performed in the processing chamber 110. The ratio can vary from approximately 0.001 to approximately 15 percent by volume. For example, when the recirculation loop 115 comprises a volume of about one liter, the process chemistry volumes can range from approximately ten micro liters to approximately one hundred fifty milliliters. In alternate embodiments, the volume and/or the ratio can be higher or lower.

The process chemistry supply system 130 can comprise a cleaning chemistry assembly (not shown) for providing cleaning chemistry for generating supercritical cleaning solutions within the processing chamber. The cleaning chemistry can include peroxides and a fluoride source. For example, the peroxides can include hydrogen peroxide, benzoyl peroxide, or any other suitable peroxide, and the fluoride sources can include fluoride salts (such as ammonium fluoride salts), hydrogen fluoride, fluoride adducts (such as organic-ammonium fluoride adducts) and combinations thereof.

Further details of fluoride sources and methods of generating supercritical processing solutions with fluoride sources are described in U.S. patent application Ser. No. 10/442,557, filed May 10, 2003, and titled “TETRA-ORGANIC AMMONIUM FLUORIDE AND HF IN SUPERCRITICAL FLUID FOR PHOTORESIST AND RESIDUE REMOVAL”, and U.S. patent application Ser. No. 10/321,341, filed Dec. 16, 2002, and titled “FLUORIDE IN SUPERCRITICAL FLUID FOR PHOTORESIST POLYMER AND RESIDUE REMOVAL,” both are incorporated by reference herein.

In addition, the cleaning chemistry can include chelating agents, complexing agents, oxidants, organic acids, and inorganic acids that can be introduced into supercritical carbon dioxide with one or more carrier solvents, such as N,N-dimethylacetamide (DMAc), gamma-butyrolactone (BLO), dimethyl sulfoxide (DMSO), ethylene carbonate (EC), N-methylpyrrolidone (NM P), dimethylpiperidone, propylene carbonate, and alcohols (such a methanol, ethanol and 1-propanol).

Furthermore, the cleaning chemistry can include solvents, co-solvents, surfactants, and/or other ingredients. Examples of solvents, co-solvents, and surfactants are disclosed in co-owned U.S. Pat. No. 6,500,605, entitled “REMOVAL OF PHOTORESIST AND RESIDUE FROM SUBSTRATE USING SUPERCRITICAL CARBON DIOXIDE PROCESS”, issued Dec. 31, 2002, and U.S. Pat. No. 6,277,753, entitled “REMOVAL OF CMP RESIDUE FROM SEMICONDUCTORS USING SUPERCRITICAL CARBON DIOXIDE PROCESS”, issued Aug. 21, 2001, both are incorporated by reference herein.

The process chemistry supply system 130 can be configured to introduce N-methylpyrrolidone (NMP), diglycol amine, hydroxylamine, di-isopropyl amine, tri-isoprpyl amine, tertiary amines, catechol, ammonium fluoride, ammonium bifluoride, methylacetoacetamide, ozone, propylene glycol monoethyl ether acetate, acetylacetone, dibasic esters, ethyl lactate, CHF₃, BF₃, HF, other fluorine containing chemicals, or any mixture thereof. Other chemicals such as organic solvents can be utilized independently or in conjunction with the above chemicals to remove organic materials. The organic solvents can include, for example, an alcohol, ether, and/or glycol, such as acetone, diacetone alcohol, dimethyl sulfoxide (DMSO), ethylene glycol, methanol, ethanol, propanol, or isopropanol (IPA). For further details, see U.S. Pat. No. 6,306,564B1, filed May 27, 1998, and titled “REMOVAL OF RESIST OR RESIDUE FROM SEMICONDUCTORS USING SUPERCRITICAL CARBON DIOXIDE”, and U.S. Pat. No. 6,509,141B2, filed Sep. 3, 1999, and titled “REMOVAL OF PHOTORESIST AND PHOTORESIST RESIDUE FROM SEMICONDUCTORS USING SUPERCRITICAL CARBON DIOXIDE PROCESS”, both are incorporated by reference herein.

Moreover, the process chemistry supply system 130 can be configured to introduce a peroxide during a cleaning and/or rinsing process. The peroxide can be introduced with any one of the above process chemistries, or any mixture thereof. The peroxide can include organic peroxides, or inorganic peroxides, or a combination thereof. For example, organic peroxides can include 2-butanone peroxide; 2,4-pentanedione peroxide; peracetic acid; t-butyl hydroperoxide; benzoyl peroxide; or m-chloroperbenzoic acid (mCPBA). Other peroxides can include hydrogen peroxide. Alternatively, the peroxide can include a diacyl peroxide, such as: decanoyl peroxide; lauroyl peroxide; succinic acid peroxide; or benzoyl peroxide; or any combination thereof. Alternatively, the peroxide can include a dialkyl peroxide, such as: dicumyl peroxide; 2,5-di(t-butylperoxy)-2,5-dimethylhexane; t-butyl cumyl peroxide; α,α-bis(t-butylperoxy)diisopropylbenzene mixture of isomers; di(t-amyl) peroxide; di(t-butyl) peroxide; or 2,5-di(t-butylperoxy)-2,5-dimethyl-3-hexyne; or any combination thereof. Alternatively, the peroxide can include a diperoxyketal, such as: 1,1-di(t-butylperoxy)-3,3,5-trimethylcyclohexane; 1,1-di(t-butylperoxy)cyclohexane; 1,1-di(t-amylperoxy)-cyclohexane; n-butyl 4,4-di(t-butylperoxy)valerate; ethyl 3,3-di-(t-amylperoxy)butanoate; t-butyl peroxy-2-ethylhexanoate; or ethyl 3,3-di(t-butylperoxy)butyrate; or any combination thereof. Alternatively, the peroxide can include a hydroperoxide, such as: cumene hydroperoxide; or t-butyl hydroperoxide; or any combination thereof. Alternatively, the peroxide can include a ketone peroxide, such as: methyl ethyl ketone peroxide; or 2,4-pentanedione peroxide; or any combination thereof. Alternatively, the peroxide can include a peroxydicarbonate, such as: di(n-propyl)peroxydicarbonate; di(sec-butyl)peroxydicarbonate; or di(2-ethylhexyl)peroxydicarbonate; or any combination thereof. Alternatively, the peroxide can include a peroxyester, such as: 3-hydroxyl-1,1-dimethylbutyl peroxyneodecanoate; α-cumyl peroxyneodecanoate; t-amyl peroxyneodecanoate; t-butyl peroxyneodecanoate; t-butyl peroxypivalate; 2,5-di(2-ethylhexanoylperoxy)-2,5-dimethylhexane; t-amyl peroxy-2-ethylhexanoate; t-butyl peroxy-2-ethylhexanoate; t-amyl peroxyacetate; t-butyl peroxyacetate; t-butyl peroxybenzoate; OO-(t-amyl)O-(2-ethylhexyl)monoperoxycarbonate; OO-(t-butyl)O-isopropyl monoperoxycarbonate; OO-(t-butyl)O-(2-ethylhexyl)monoperoxycarbonate; polyether poly-t-butylperoxy carbonate; or t-butyl peroxy-3,5,5-trimethylhexanoate; or any combination thereof. Alternatively, the peroxide can include any combination of peroxides listed above.

The process chemistry supply system 130 can comprise a rinsing chemistry assembly (not shown) for providing rinsing chemistry for generating supercritical rinsing solutions within the processing chamber. The rinsing chemistry can include one or more organic solvents including, but not limited to, alcohols and ketones. For example, the rinsing chemistry can comprise solvents, such as N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, and alcohols (such a methanol, ethanol and 2-propanol).

Moreover, the process chemistry supply system 130 can be configured to introduce treating chemistry for curing, cleaning, healing (or restoring the dielectric constant of low-k materials), or sealing, or any combination, low dielectric constant films (porous or non-porous). The chemistry can include hexamethyldisilazane (HMDS), chlorotrimethylsilane (TMCS), trichloromethylsilane (TCMS), dimethylsilyidiethylamine (DMSDEA), tetramethyldisilazane (TMDS), trimethylsilyldimethylamine (TMSDMA), dimethylsilyldimethylamine (DMSDMA), trimethylsilyldiethylamine (TMSDEA), bistrimethylsilyl urea (BTSU), bis(dimethylamino)methyl silane (B[DMA]MS), bis(dimethylamino)dimethyl silane (B[DMA]DS), HMCTS, dimethylaminopentamethyldisilane (DMAPMDS), dimethylaminodimethyldisilane (DMADMDS), disila-aza-cyclopentane (TDACP), disila-oza-cyclopentane (TDOCP), methyltrimethoxysilane (MTMOS), vinyltrimethoxysilane (VTMOS), or trimethylsilylimidazole (TMSI). Additionally, the chemistry can include N-tert-butyl-1,1-dimethyl-1-(2,3,4,5-tetramethyl-2,4-cyclopentadiene-1-yl)silanamine, 1,3-diphenyl-1,1,3,3-tetramethyldisilazane, or tert-butylchlorodiphenylsilane. For further details, see U.S. patent application Ser. No. 10/682,196, filed Oct. 10, 2003, and titled “METHOD AND SYSTEM FOR TREATING A DIELECTRIC FILM”, and U.S. patent application Ser. No. 10/379,984, filed Mar. 4, 2003, and titled “METHOD OF PASSIVATING LOW DIELECTRIC MATERIALS IN WAFER PROCESSING”, both incorporated by reference herein.

The processing system 100 can comprise a high-pressure fluid supply system 140. As shown in FIG. 1, the high-pressure fluid supply system 140 can be coupled to the recirculation system 120 using one or more lines 145, but this is not required. The inlet line 145 can be equipped with one or more back-flow valves, and/or heaters (not shown) for controlling the fluid flow from the high-pressure fluid supply system 140. In alternate embodiments, high-pressure fluid supply system 140 can be configured differently and coupled differently. For example, the high-pressure fluid supply system 140 can be coupled to the process module 110.

The high-pressure fluid supply system 140 can comprise a carbon dioxide source (not shown) and a plurality of flow control elements (not shown) for generating a supercritical fluid. For example, the carbon dioxide source can include a CO₂ feed system, and the flow control elements can include supply lines, valves, filters, pumps, and heaters. The high-pressure fluid supply system 140 can comprise an inlet valve (not shown) that is configured to open and close to allow or prevent the stream of supercritical carbon dioxide from flowing into the processing chamber 108. For example, controller 180 can be used to determine fluid parameters such as pressure, temperature, process time, and flow rate.

The processing system 100 can also comprise a pressure control system 160. As shown in FIG. 1, the pressure control system 160 can be coupled to the process module 110 using one or more lines 165, but this is not required. Line 165 can be equipped with one or more back-flow valves, pumps, and/or heaters (not shown) for controlling the fluid flow to pressure control system 160. In alternate embodiments, pressure control system 160 can be configured differently and coupled differently. For example, the pressure control system 160 can also include one or more pumps (not shown), and a sealing means (not shown) for sealing the processing chamber. In addition, the pressure control system 160 can comprise means for raising and lowering the substrate and/or the chuck.

In addition, the processing system 100 can comprise an exhaust control system 150. Alternately, an exhaust system may not be required. As shown in FIG. 1, the exhaust control system 150 can be coupled to the process module 110 using one or more lines 155, but this is not required. Line 155 can be equipped with one or more back-flow valves, and/or heaters (not shown) for controlling the fluid flow to the exhaust control system 150. In alternate embodiments, exhaust control system 150 can be configured differently and coupled differently. The exhaust control system 150 can include an exhaust gas collection vessel (not shown) and can be used to remove contaminants from the processing fluid. Alternately, the exhaust control system 150 can be used to recycle the processing fluid.

In one embodiment, controller 180 can comprise a processor 182 and a memory 184. Memory 184 can be coupled to processor 182, and can be used for storing information and instructions to be executed by processor 182. Alternately, different controller configurations can be used. In addition, controller 180 can comprise a port 185 that can be used to couple processing system 100 to another system (not shown). Furthermore, controller 180 can comprise input and/or output devices (not shown).

In addition, one or more of the processing elements (110, 120, 130, 140, 150, 160, and 180) can include memory (not shown) for storing information and instructions to be executed during processing and processors for processing information and/or executing instructions. For example, the memory can be used for storing temporary variables or other intermediate information during the execution of instructions by the various processors in the system. One or more of the processing elements can comprise the means for reading data and/or instructions from a computer readable medium. In addition, one or more of the processing elements can comprise the means for writing data and/or instructions to a computer readable medium.

Memory devices can include at least one computer readable medium or memory for holding computer-executable instructions programmed according to the teachings of the invention and for containing data structures, tables, records, or other data described herein.

The processing system 100 can perform a portion or all of the processing steps of the invention in response to the controller 180 executing one or more sequences of one or more computer-executable instructions contained in a memory. Such instructions can be received by the controller from another computer, a computer readable medium, or a network connection.

Stored on any one or on a combination of computer readable media, the present invention includes software for controlling the processing system 100, for driving a device or devices for implementing the invention, and for enabling the processing system 100 to interact with a human user and/or another system, such as a factory system. Such software can include, but is not limited to, device drivers, operating systems, development tools, and applications software. Such computer readable media further includes the computer program product of the present invention for performing all or a portion (if processing is distributed) of the processing performed in implementing the invention.

The term “computer readable medium” as used herein refers to any medium that participates in providing instructions to a processor for execution and/or that participates in storing information before, during, and/or after executing an instruction. A computer readable medium can take many forms, including but not limited to, non-volatile media, volatile media, and transmission media. The term “computer-executable instruction” as used herein refers to any computer code and/or software that can be executed by a processor, that provides instructions to a processor for execution and/or that participates in storing information before, during, and/or after executing an instruction.

Controller 180, processor 182, memory 184 and other processors and memory in other system elements as described thus far can, unless indicated otherwise below, be constituted by components known in the art or constructed according to principles known in the art. The computer readable medium and the computer executable instructions can also, unless indicated otherwise below, be constituted by components known in the art or constructed according to principles known in the art.

Controller 180 can use port 185 to obtain computer code and/or software from another system (not shown), such as a factory system. The computer code and/or software can be used to establish a control hierarchy. For example, the processing system 100 can operate independently, or can be controlled to some degree by a higher-level system (not shown).

The controller 180 can receive data from and/or send data to the pre-injection assembly 170. The controller 180 can include means for determining a temperature of the processing fluid in the pre-injection assembly 170, means for comparing the temperature to a threshold value, and means for altering the temperature of the processing fluid when the temperature is different from the threshold value. For example, additional cooling can be provided to the fluid in the recirculation loop when the temperature is greater than or equal to the threshold value, and additional heating can be provided to the fluid in the recirculation loop when the temperature is less than the threshold value.

In addition, the controller 180 can receive data from and/or send data to the temperature controlled process tubing 121 and/or the temperature-controlled process tubing 125. The controller 180 can include means for determining a temperature of the processing fluid in the process tubing (121, 125, and 171), means for comparing the temperature to a threshold value, and means for altering the temperature of the processing fluid when the temperature is different from the threshold value. For example, additional cooling can be provided to the fluid in the recirculation loop when the temperature is greater than or equal to the threshold value, and additional heating can be provided to the fluid in the recirculation loop when the temperature is less than the threshold value.

The controller 180 can use data from the pre-injection assembly 170 and/or the process tubing (121, 125, and 171) to determine when to alter, pause, and/or stop a process. The controller 180 can use the data and operational rules to determine when to change a process and how to change the process, and rules can be used to specify the action taken for normal processing and the actions taken on exceptional conditions. Operational rules can be used to determine which processes are monitored and which data is used. For example, rules can be used to determine how to manage the data when a process is changed, paused, and/or stopped. In general, rules allow system and/or tool operation to change based on the dynamic state of the system.

Controller 180 can receive, send, use, and/or generate pre-process data, process data, and post-process data, and this data can include lot data, batch data, run data, composition data, and history data. Pre-process data can be associated with an incoming substrate and can be used to establish an input state for a substrate and/or a current state for a process module. Process data can include process parameters. Post processing data can be associated with a processed substrate and can be used to establish an output state for a substrate

The controller 180 can use the pre-process data to predict, select, or calculate a process recipe to use to process the substrate. A process recipe can include a multi-step process involving a set of process modules. Post-process data can be obtained at some point after the substrate has been processed. For example, post-process data can be obtained after a time delay that can vary from minutes to days.

In one embodiment, the controller 180 can compute a predicted fluid temperature based on the pre-process data, the process characteristics, and a process model. A process model can provide the relationship between one or more process recipe parameters, such as the temperature of the processing fluid and one or more process results. The controller 180 can compare the predicted value to the measured value to determine when to alter, pause, and/or stop a process.

In other embodiments, a reaction rate model can be used along with an expected fluid temperature at the substrate surface to compute a predicted value for the processing time, or a solubility model can be used along with an expected fluid temperature at the substrate surface to compute a predicted value for the processing time.

In another embodiment, the controller 180 can use historical data and/or process models to compute an expected value for the temperature of the fluid at various times during the process. The controller 180 can compare an expected temperature value to a measured temperature value to determine when to alter, pause, and/or stop a process.

In a supercritical cleaning/rinsing process, the desired process result can be a process result that is measurable using an optical measuring device, such as a SEM and/or TEM. For example, the desired process result can be an amount of residue and/or contaminant in a via or on the surface of a substrate. After one or more cleaning process run, the desired process can be measured.

In addition, at least one of the processing elements (110, 120, 130, 140, 150, 160, 170, and 180) can comprise a GUI component and/or a database component (not shown). In alternate embodiments, the GUI component and/or the database component may not be required.

It will be appreciated that the controller 180 can perform other functions in addition to those discussed here. The controller 180 can monitor variables associated with the other components in the processing system 100 and take actions based on these variables. For example, the controller 180 can process these variables, display these variables and/or results on a GUI screen, determine a fault condition, determine a response to a fault condition, and alert an operator.

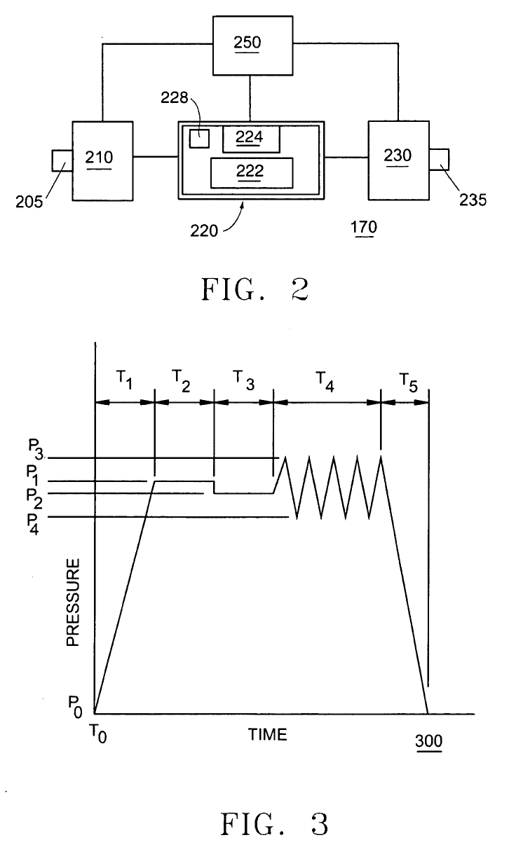

FIG. 2 illustrates a simplified block diagram of a pre-injection assembly in accordance with an embodiment of the invention. In the illustrated embodiment, a pre-injection assembly 170 is shown that includes a fluid inlet means 210 having an input port 205, a supply assembly 220, a fluid outlet means 230 having an output port 235, and a controller 250. In alternate embodiments, different configurations can be used. For example, the pre-injection assembly 170 can be a portion of the high-pressure fluid supply system 140.

Input port 205 can be coupled to a high-pressure fluid source (not shown). For example, the high-pressure fluid source can provide a process fluid that can comprise gaseous, liquid, supercritical, or near-supercritical carbon dioxide, or combinations thereof, and the high-pressure fluid source can include one or more fluid cylinders, and/or one or more storage vessels.

The fluid inlet means 210 can comprise a flow control valve (not shown) that can be used for controlling the flow into the pre-injection assembly 170. In an alternate embodiment, the fluid inlet means 210 can include a heater and a sensor for pre-heating the fluid. In additional embodiments, the fluid inlet means 210 can include a regulator, a valve, a pump, a vent, a coupling, a filter, piping, and/or safety devices (not shown). In addition, the fluid inlet means 210 can comprise one or more flow restrictors for regulating the flow. For example, flow restrictors having different sizes can be used to vary the flow rate, and smaller sized orifices can be used for slower flow and larger sized orifices for faster flow.

In one embodiment, the fluid inlet means 210 can be coupled to a supply assembly 220. In an alternate embodiment, a filter (not shown) can be used to couple the fluid inlet means 210 to a supply assembly 220.

Supply assembly 220 can comprise a chamber 222, heater subassembly 224, insulation 226, and a sensor subassembly 228. For example, the chamber 222 can be configured using a high strength metal, such as stainless steel 316L. Chamber 222 can have a volume that can vary from approximately three times to approximately twenty times the volume of the recirculation loop 115 (FIG. 1). The chamber 222 can have an operating pressure up to 10,000 psi, and an operating temperature up to 300 degrees Celsius.

Heater subassembly 224 can comprise a heating element (not shown) and can cover at least ninety percent of the outside surface area of the chamber 222. For example, heating element 224 can include a high temperature blanket heater, such as a silicone blanket heater from Watlow. Insulation 226 can comprise a high temperature material (not shown) and can cover at least ninety percent of the outside surface area of the heating element. For example, insulation 226 can include high-temperature insulation, such as Silicone foam from Quantum Silicones. Heater subassembly 224 and insulation 226 can maintain an operating temperature up to 300 degrees Celsius in the chamber 222. Heater subassembly 224 and insulation 226 can be configured using one or more pieces that can be easily replaced during a maintenance operation.

Sensor subassembly 228 can comprise one or more temperature sensors (not shown) coupled to the chamber 222 at different locations. Alternately, the sensor subassembly 228 can also include a flow sensor and/or pressure sensor (not shown) that can be coupled to the chamber 222 at different locations. Sensor subassembly 228 can measure operating temperatures up to 300 degrees Celsius in the chamber 222.

The sensor can comprise a temperature sensor that can include a thermocouple, a temperature-indicating resistor, a radiation type temperature sensor, a thermistor, a thermometer, a pyrometer, a micro-electromechanical (MEM) device, or a resistance temperature detector (RTD), or a combination thereof. The sensor can include a contact-type sensor or a non-contact sensor. For example, a K-type thermocouple, a Pt sensor, a bimetallic thermocouple, or a temperature indicating platinum resistor can be used. For example, sensor subassembly 228 can include a high temperature sensor, such as k-type thermocouple from Omega.

The controller 250 can be coupled to the heater subassembly 224 and the sensor subassembly 228 and can be used to control the heater subassembly 224 and the sensor subassembly 228. Alternately, controller 250 may not be required. For example, controller 180 can be used to control the heater subassembly 224 and the sensor subassembly 228. In additional embodiments, the supply assembly 220 can include a regulator, a valve, a pump, a vent, a coupling, a filter, piping, a cooling device, and/or safety devices (not shown).

In one embodiment, the supply assembly 220 can be coupled to a fluid outlet means 230. In an alternate embodiment, a filter (not shown) can be used to couple the supply assembly 220 to the fluid outlet means 230.

The fluid outlet means 230 can comprise a flow control valve (not shown) that can be used for controlling the flow out of the pre-injection assembly 170. For example, a multi-port valve can be used. In an alternate embodiment, the fluid outlet means 230 can include a heater and a sensor for post-heating the fluid. In additional embodiments, the fluid outlet means 230 can include a regulator, a valve, a sensor, a pump, a vent, a coupling, a filter, piping, and/or safety devices (not shown). For example, the fluid outlet means 230 can include a measuring means (not shown) for measuring the flow rate and/or temperature of the fluid passing therethrough. In addition, the fluid outlet means 230 can comprise one or more flow restrictors for regulating the flow. For example, flow restrictors having different sizes can be used to vary the flow rate, and smaller sized orifices can be used for slower flow and larger sized orifices for faster flow.

The pre-injection assembly 170 can be used to provide a temperature controlled supercritical fluid that can include supercritical carbon dioxide.

In an alternate embodiment, the pre-injection assembly 170 can be used to provide a temperature controlled supercritical fluid that can include supercritical carbon dioxide admixed with process chemistry. For example, the pre-injection assembly 170 can be coupled to the process chemistry supply system 130 (FIG. 1), and the can comprise a mixing vessel (not shown) and/or a storage vessel (not shown), and one or more vessels can be heated.

Controller 250 can also be used to control the fluid inlet means 210 and fluid outlet means 230. Alternately, controller 250 may not be required. For example, controller 180 can be used to control the fluid inlet means 210 and fluid outlet means 230.

During substrate processing, providing processing fluids at an incorrect temperature can have a negative affect on the process. For example, an incorrect temperature can affect the process chemistry, process dropout, and process uniformity. In one embodiment, the pre-injection assembly 170 is used during a major portion of the substrate processing so that the impact of temperature on the process is minimized.

In another embodiment, the pre-injection assembly 170 can be used during a maintenance or system cleaning operation in which cleaning chemistry is used to remove process by-products and/or particles from the interior surfaces of the system. This is a preventative maintenance operation in which maintaining the correct temperature prevents material from adhering to the interior surfaces of the system that can be dislodged later during processing and that can cause unwanted particle deposition on a substrate.

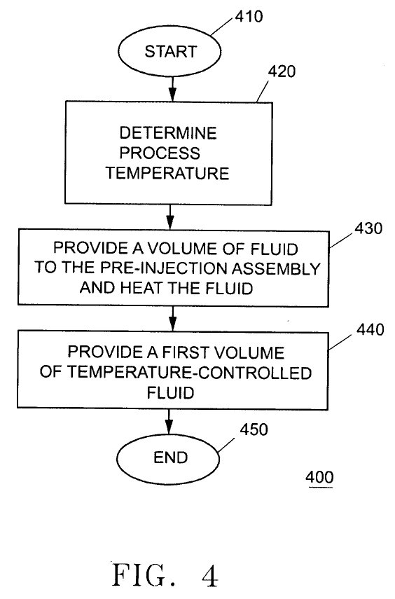

FIG. 3 illustrates an exemplary graph of pressure versus time for a supercritical process step in accordance with embodiments of the invention. In the illustrated embodiment, a graph 300 of pressure versus time is shown, and the graph 300 can be used to represent a supercritical cleaning process step, a supercritical rinsing process step, or a supercritical curing process step, or a combination thereof. Alternately, different pressures, different timing, and different sequences can be used for different processes. In addition, although a single time sequence is illustrated in FIG. 3, this is not required for the invention. Alternately, multi-sequence processes can be used.

Referring to FIGS. 1-3, prior to an initial time T₀, the substrate to be processed can be placed within the processing chamber 108 and the processing chamber can be sealed. For example, during cleaning, rinsing, and/or curing processes, a substrate can have post-etch and/or post-ash residue thereon. The substrate, the processing chamber, and the other elements in the recirculation loop 115 can be heated to an operational temperature that can range from approximately 40 to approximately 300 degrees Celsius. For example, the temperature of temperature controlled process tubing (121, 125, and 171) can be established and/or maintained at the required operational value. Furthermore, temperature of pre-injection assembly 170 can be established and/or maintained at the required operational value.

During time T₁, the processing chamber 108 and the other elements in the recirculation loop 115 can be pressurized. During at least one portion of the time T₁, the high-pressure fluid supply system 140 and/or the pre-injection assembly 170 can be coupled into the flow path and can be used to provide temperature controlled carbon dioxide into the processing chamber and/or other elements in the recirculation loop 115. For example, the temperature variation of the temperature-controlled carbon dioxide can be controlled to be less than approximately ten degrees Celsius during the pressurization process. Alternately, the temperature variation can be controlled to be less than approximately five degrees Celsius.

During time T₁, a pump (not shown) in the recirculation system 120 can be started and can be used to circulate the temperature controlled fluid through the monitoring system, the processing chamber, and the other elements in the recirculation loop. In one embodiment, sensors in the temperature controlled process tubing (121, 125, and 171) can operate while the fluid is being circulated and can provide temperature data for the fluid flowing at different points in the loop. Alternately, these sensors may not be operated during this portion of the time T₁.

In one embodiment, when the pressure in the processing chamber 108 exceeds a critical pressure Pc (1,070 psi), process chemistry can be injected into the recirculation loop 115 using the process chemistry supply system 130. In one embodiment, additional high-pressure fluid is not provided when the process chemistry is injected. Alternately, additional high-pressure fluid can be provided when the process chemistry is injected.

In other embodiments, process chemistry can be injected into the processing chamber 108 before the pressure exceeds the critical pressure Pc (1,070 psi) using the process chemistry supply system 130. For example, the injection(s) of the process chemistries can begin upon reaching about 1100-1200 psi. In other embodiments, process chemistry is not injected during the T₁ period.

In addition, sensors in the processing module 110 and/or the temperature controlled process tubing (121, 125, and 171) can provide data before, during, and/or after the process chemistry is injected, and data, such as temperature data, can be used to control the injection process. Process chemistry can be injected in a linear fashion, and the injection time can be based on a recirculation time. For example, the recirculation time can be determined based on the length of the recirculation path and the flow rate. In other embodiments, process chemistry can be injected in a non-linear fashion. For example, process chemistry can be injected in one or more steps.

The process chemistry can include a cleaning agent, a rinsing agent, or a curing agent, or a combination thereof that is injected into the supercritical fluid. One or more injections of process chemistries can be performed over the duration of time T₁ to generate a supercritical processing solution with the desired concentrations of chemicals. The process chemistry, in accordance with the embodiments of the invention, can also include one more or more carrier solvents.

Still referring to FIGS. 1-3, during a second time T₂, the supercritical processing solution can be re-circulated over the substrate and through the temperature controlled process tubing (121, 125, and 171), the processing chamber 108, and the other elements in the recirculation loop 115.

In one embodiment, sensors in the processing module 110 and/or the temperature controlled process tubing (121, 125, and 171) can provide data while the supercritical processing solution is being re-circulated, and data, such as temperature data, can be used to control the process. Alternately, one or more sensors may not be operated while the supercritical processing solution is being re-circulated. The high-pressure fluid supply system 140 and/or the pre-injection assembly 170 can be used to control the chemical composition while the supercritical processing solution is being re-circulated. In one embodiment, additional high-pressure fluid is not provided, and additional process chemistry is not injected during the second time T₂. Alternatively, additional high-pressure fluid can be provided, and/or additional process chemistry can be injected during the second time T₂.

The processing chamber 108 can operate at a pressure above 1,500 psi during the second time T₂. For example, the pressure can range from approximately 2,500 psi to approximately 3,100 psi, but can be any value so long as the operating pressure is sufficient to maintain supercritical conditions. The supercritical processing solution can be circulated over the substrate and through the recirculation loop 115. The supercritical conditions within the processing chamber 108 and the other elements in the recirculation loop 115 are maintained during the second time T₂, and the supercritical processing solution continues to be circulated over the substrate and through the processing chamber 108 and the other elements in the recirculation loop 115. The recirculation system 120 can be used to regulate the flow of the supercritical processing solution through the processing chamber 108 and the other elements in the recirculation loop 115.

Still referring to FIGS. 1-3, during a third time T₃, one or more push-through processes can be performed. The high-pressure fluid supply system 140 and/or the pre-injection assembly 170 can comprise means for providing a first volume of temperature-controlled fluid during a push-through process, and the first volume can be larger than the volume of the recirculation loop. Alternately, the first volume can be less than or approximately equal to the volume of the recirculation loop. In addition, the temperature differential within the first volume of temperature-controlled fluid during the push-through process can be controlled to be less than approximately ten degrees Celsius. Alternately, the temperature differential can be controlled to be less than approximately five degrees Celsius.

In one embodiment, a sensor in the processing module 110, a sensor in the pre-injection assembly 170, or a sensor in the temperature controlled process tubing (121, 125, and 171), or a combination thereof can provide data before, during, and/or after a push-through process is performed, and data, such as temperature data, can be used to control the push-through process. Alternately, one or more sensors may not be operated during a push-through process. The sensor data can be used to control the fluid temperature and/or flow rate during a push-through process. For example, during the third time T₃, one or more volumes of temperature controlled supercritical carbon dioxide can be fed into the recirculation loop 115 from the high-pressure fluid supply system 140 and/or the pre-injection assembly 170, and the supercritical processing solution along with process residue suspended or dissolved therein can be displaced from the processing chamber 108 and the other elements in the recirculation loop 115 through the exhaust control system 150. Providing temperature-controlled fluid during the push-through process prevents process residue suspended or dissolved within the fluid being displaced from the processing chamber 108 and the other elements in the recirculation loop 115 from dropping out and/or adhering to the processing chamber 108 and the other elements in the recirculation loop 115. In addition, during the third time T₃, the temperature of the fluid supplied by the high-pressure fluid supply system 140 and/or the pre-injection assembly 170 can vary over a wider temperature range than the range used during the second time T₂.

In the illustrated embodiment shown in FIG. 3, a single second time T₂ is followed by a single third time T₃, but this is not required. In alternate embodiments, other time sequences can be used to process a substrate.

During a fourth time T₄, a pressure cycling process can be performed, and the processing chamber 108 can be cycled through one or more decompression and compression cycles. Alternately, one or more pressure cycles can occur during the push-through process. In other embodiments, a pressure cycling process is not required. The pressure can be cycled between a first pressure P₃ and a second pressure P₄ one or more times. In alternate embodiments, the first pressure P₃ and a second pressure P₄ can vary. In one embodiment, the pressure can be lowered by venting through the exhaust control system 150. For example, pressure cycling can be accomplished by lowering the pressure to below approximately 1,500 psi and raising the pressure to above approximately 2,500 psi. The pressure can be increased by using the high-pressure fluid supply system 140 and/or the pre-injection assembly 170 to provide additional high-pressure fluid.

The high-pressure fluid supply system 140 and/or the pre-injection assembly 170 can comprise means for providing a first volume of temperature-controlled fluid during a compression cycle, and the first volume can be larger than the volume of the recirculation loop. Alternately, the first volume can be less than or approximately equal to the volume of the recirculation loop. In addition, the temperature differential within the first volume of temperature-controlled fluid during the compression cycle can be controlled to be less than approximately ten degrees Celsius. Alternately, the temperature differential can be controlled to be less than approximately five degrees Celsius.

In addition, the high-pressure fluid supply system 140 and/or the pre-injection assembly 170 can comprise means for providing a second volume of temperature-controlled fluid during a decompression cycle, and the second volume can be larger than the volume of the recirculation loop. Alternately, the second volume can be less than or approximately equal to the volume of the recirculation loop. In addition, the temperature differential within the second volume of temperature-controlled fluid during the decompression cycle can be controlled to be less than approximately ten degrees Celsius. Alternately, the temperature differential can be controlled to be less than approximately five degrees Celsius.

In one embodiment, a sensor in the processing module 110, a sensor in the pre-injection assembly 170, or a sensor in the temperature controlled process tubing (121, 125, and 171), or a combination thereof can provide data before, during, and/or after a pressure cycling process is performed, and data, such as temperature data, can be used to control the pressure cycling process. Alternately, one or more sensors may not be operated during a pressure cycling process. The sensor data can be used to control the fluid temperature and/or flow rate during a pressure cycling process. For example, during the fourth time T₄, one or more volumes of temperature controlled supercritical carbon dioxide can be fed into the processing chamber 108 and the other elements in the recirculation loop 115 from high-pressure fluid supply system 140 and/or the pre-injection assembly 170, and the supercritical processing solution along with process residue suspended or dissolved therein can be displaced from the processing chamber 108 and the other elements in the recirculation loop 115 through the exhaust control system 150.

Providing temperature-controlled fluid during the pressure cycling process prevents process residue suspended or dissolved within the fluid being displaced from the processing chamber 108 and the other elements in the recirculation loop 115 from dropping out and/or adhering to the processing chamber 108 and the other elements in the recirculation loop 115. In addition, during the fourth time T₄, the temperature of the fluid supplied by the high-pressure fluid supply system 140 and/or the pre-injection assembly 170 can vary over a wider temperature range than the range used during the second time T₂.

In the illustrated embodiment shown in FIG. 3, a single third time T₃ is followed by a single fourth time T₄, but this is not required. In alternate embodiments, other time sequences can be used to process a substrate.

In an alternate embodiment, the high-pressure fluid supply system 140 and/or the pre-injection assembly 170 can be switched off during a portion of the fourth time T₄.

During a fifth time T₅, the processing chamber 108 can be returned to lower pressure. For example, after a supercritical process is completed, the processing chamber can be vented or exhausted to a pressure compatible with a transfer system

In one embodiment, a sensor in the processing module 110, a sensor in the pre-injection assembly 170, or a sensor in the temperature controlled process tubing (121, 125, and 171), or a combination thereof can provide data before, during, and/or after a venting process is performed, and data, such as temperature data, can be used to control the venting process. Alternately, one or more sensors may not be operated during a venting process. The high-pressure fluid supply system 140 and/or the pre-injection assembly 170 can comprise means for providing a volume of temperature-controlled fluid during a venting process, and the volume can be larger than the volume of the recirculation loop. Alternately, the volume can be less than or approximately equal to the volume of the recirculation loop. For example, during the fifth time T₅, one or more volumes of temperature controlled supercritical carbon dioxide can be fed into the processing chamber 108 and the other elements in the recirculation loop 115 from the high-pressure fluid supply system 140 and/or the pre-injection assembly 170, and the remaining processing solution along with process residue suspended or dissolved therein can be displaced from the processing chamber 108 and the other elements in the recirculation loop 115 through the exhaust control system 150.

In the illustrated embodiment shown in FIG. 3, a single fourth time T₄ is followed by a single fifth time T₅, but this is not required. In alternate embodiments, other time sequences can be used to process a substrate.

In one embodiment, during a portion of the fifth time T₅, the high-pressure fluid supply system 140 and/or the pre-injection assembly 170 can be switched off. In addition, the temperature of the fluid supplied by the high-pressure fluid supply system 140 and/or the pre-injection assembly 170 can vary over a wider temperature range than the range used during the second time T₂. For example, the temperature can range below the temperature required for supercritical operation.

For substrate processing, the chamber pressure can be made substantially equal to the pressure inside of a transfer chamber (not shown) coupled to the processing chamber. In one embodiment, the substrate can be moved from the processing chamber into the transfer chamber, and moved to a second process apparatus or module to continue processing.

In the illustrated embodiment shown in FIG. 3, the pressure returns to an initial pressure P₀, but this is not required for the invention. In alternate embodiments, the pressure does not have to return to P₀, and the process sequence can continue with additional time steps such as those shown in time steps T₁, T₂, T₃, T₄, or T₅

The graph 300 is provided for exemplary purposes only. It will be understood by those skilled in the art that a supercritical processing step can have any number of different time/pressures or temperature profiles without departing from the scope of the invention. Further, any number of cleaning, rinsing, and/or curing process sequences with each step having any number of compression and decompression cycles are contemplated. In addition, as stated previously, concentrations of various chemicals and species within a supercritical processing solution can be readily tailored for the application at hand and altered at any time within a supercritical processing step.

FIG. 4 illustrates a flow diagram of a method for monitoring the temperature of a high-pressure processing fluid flowing through a recirculation loop in a high-pressure processing system in accordance with an embodiment of the invention. Procedure 400 starts in 410 wherein a substrate can be positioned within a processing chamber that is part of the recirculation loop.

In 420, a process temperature can be determined.

In 430, a volume of fluid can be provided to the pre-injection assembly and the pre-injection assembly can heat the volume of fluid to the process temperature.

In 440, a first volume of temperature-controlled fluid can be provided from the pre-injection assembly to the processing chamber and the other elements in the recirculation loop. Alternately, the pre-injection assembly can provide different volumes to the processing chamber and/or other elements in the recirculation loop.

In 450, an additional volume of fluid can be provided to the pre-injection assembly and the pre-injection assembly can heat the additional volume of fluid to the process temperature.

In 460, procedure 400 can end. For example, the pre-injection assembly can maintain the fluid in the pre-injection assembly at the process temperature.

While the invention has been described in terms of specific embodiments incorporating details to facilitate the understanding of the principles of construction and operation of the invention, such reference herein to specific embodiments and details thereof is not intended to limit the scope of the claims appended hereto. It will be apparent to those skilled in the art that modifications may be made in the embodiments chosen for illustration without departing from the spirit and scope of the invention.

What is claimed is:

1. A system for regulating a processing fluid temperature within a high-pressure processing system, the system comprising:
a high-pressure, temperature-controlled recirculation loop comprising a high-pressure, temperature-controlled processing chamber and a high-pressure, temperature-controlled recirculation system coupled to the high-pressure, temperature-controlled processing chamber, wherein the processing fluid flows through the high-pressure, temperature-controlled recirculation loop;
a pre-injection assembly coupled to the high-pressure, temperature-controlled recirculation loop and comprising means for supplying high-pressure, temperature-controlled fluid to the high-pressure, temperature-controlled recirculation loop;
a process chemistry supply system coupled to the high-pressure, temperature-controlled recirculation loop and comprising means for supplying process chemistry to the high-pressure, temperature-controlled recirculation loop; and
a controller coupled to the high-pressure, temperature-controlled processing chamber, the high-pressure, temperature-controlled recirculation system, the pre-injection assembly, and the process chemistry supply system wherein the controller comprises means for determining required process temperature data, means for obtaining measured temperature data for the processing fluid in the pre-injection assembly, means for comparing the required process temperature data to the measured temperature data, and means for changing the temperature of the processing fluid in the pre-injection assembly when the measured temperature data is substantially greater than or substantially less than the required process temperature data.

2. The system as claimed in claim 1, wherein the pre-injection assembly comprises:
a fluid inlet means comprising an input port;
a supply assembly coupled to the fluid inlet means;
a fluid outlet means comprising an output port and being coupled to the supply assembly; and
a controller coupled to the fluid inlet means, coupled to the supply assembly, and coupled to the fluid outlet means.

3. The system as claimed in claim 2, wherein the supply assembly comprises a chamber, heater assembly, insulation, and a sensor subassembly.

4. The system as claimed in claim 3, wherein the chamber volume is between approximately three times and approximately twenty times the volume of the high-pressure, temperature-controlled recirculation loop and the chamber has an operating pressure up to 10,000 psi, and an operating temperature up to 300 degrees Celsius.

5. The system as claimed in claim 3, wherein the heater subassembly comprises a removable high temperature blanket heater.

6. The system as claimed in claim 3, wherein the insulation comprises a removable high-temperature insulating blanket.

7. The system as claimed in claim 3, wherein the sensor subassembly comprises a temperature sensor, a flow sensor, a pressure sensor, or a combination thereof.

8. The system as claimed in claim 7, wherein the temperature sensor comprises a thermocouple, a temperature-indicating resistor, a radiation type temperature sensor, a thermistor, a thermometer, a pyrometer, a micro-electromechanical (MEM) device, or a resistance temperature detector (RTD), or a combination thereof.

9. The system as claimed in claim 3, wherein the sensor subassembly is configured to operate at pressures above 3000 psi.

10. The system as claimed in claim 1, wherein the processing fluid comprises gaseous, liquid, supercritical, or near-supercritical carbon dioxide, or a combination of two or more thereof.

11. The system as claimed in claim 1, wherein the process chemistry comprises a cleaning agent, a rinsing agent, a curing agent, a drying agent, or an etching agent, or a combination of two or more thereof.

12. The system as claimed in claim 1, wherein the high-pressure, temperature-controlled recirculation loop further comprises temperature controlled process tubing coupling the high-pressure, temperature-controlled processing chamber to the high-pressure, temperature-controlled recirculation system, wherein the processing fluid flows through the temperature controlled process tubing.

13. The system as claimed in claim 12, wherein the temperature controlled process tubing comprises a heater and an insulation layer.

14. A method of regulating a processing fluid temperature within a high-pressure processing system comprising a pre-injection assembly coupled to a high-pressure, temperature-controlled recirculation loop, the method comprising:
sealing a substrate in a processing chamber coupled to the pre-injection assembly;
pressurizing the high-pressure, temperature-controlled recirculation loop to a supercritical pressure, wherein the pre-injection assembly pressurizes the recirculation loop using a first volume of temperature controlled fluid, and wherein a temperature variation of the first volume of temperature controlled fluid during pressurizing is less than approximately ten degrees Celsius;
processing the substrate using a supercritical cleaning process, a supercritical rinsing process, a supercritical curing process, or a supercritical etching process, or a combination thereof;
performing a push-through process, wherein the pre-injection supply subassembly provides a second volume of temperature controlled fluid, the second volume being larger than the volume of the processing chamber, wherein the temperature differential within the second volume of temperature controlled fluid during the push-through process is less than approximately ten degrees Celsius;
performing a pressure cycling process, wherein the fluid supply subassembly provides a third volume of temperature controlled fluid during a first portion of the pressure cycling process and provides a fourth volume of temperature controlled fluid during a second portion of the pressure cycling process, the third volume and the fourth volume being larger than the volume of the processing chamber, and wherein the temperature differential within the third volume of temperature controlled fluid being less than approximately ten degrees Celsius, and the temperature differential within the fourth volume of temperature controlled fluid being less than approximately ten degrees Celsius;
performing a chamber venting process; and
removing the substrate.

15. The method of operating a processing system as claimed in claim 14 further comprising:
supplying a first quantity of a fluid to the pre-injection assembly;
determining a required temperature for the first volume of temperature controlled fluid;
determining a temperature difference between the temperature of the fluid in the pre-injection assembly and the required temperature for the first volume of temperature controlled fluid;
controlling the temperature of the fluid in the pre-injection assembly in response to the temperature difference; and
flowing the first volume of the temperature controlled fluid from the pre-injection assembly.

16. The method of operating a processing system as claimed in claim 15 further comprising keeping the temperature difference less than approximately five degrees Celsius.

17. The method of operating a processing system as claimed in claim 14 further comprising:
supplying a second quantity of a fluid to the pre-injection assembly;
determining a required temperature for the second volume of temperature controlled fluid;
determining a temperature difference between the temperature of the fluid in the pre-injection assembly and the required temperature for the second volume of temperature controlled fluid;
controlling the temperature of the fluid in the pre-injection assembly in response to the temperature difference; and
flowing the second volume of the temperature controlled fluid from the pre-injection assembly.

18. The method of operating a processing system as claimed in claim 17 further comprising keeping the temperature difference less than approximately five degrees Celsius.

19. The method of operating a processing system as claimed in claim 14 further comprising:
supplying a third quantity of a fluid to the pre-injection assembly;
determining a required temperature for the third volume of temperature controlled fluid;
determining a temperature difference between the temperature of the fluid in the pre-injection assembly and the required temperature for the third volume of temperature controlled fluid;
controlling the temperature of the fluid in the pre-injection assembly in response to the temperature difference; and
flowing the third volume of the temperature controlled fluid from the pre-injection assembly.

20. The method of operating a processing system as claimed in claim 18 further comprising keeping the temperature difference less than approximately five degrees Celsius.

21. The method of operating a processing system as claimed in claim 14 further comprising:
supplying a fourth quantity of a fluid to the pre-injection assembly;
determining a required temperature for the fourth volume of temperature controlled fluid;
determining a temperature difference between the temperature of the fluid in the pre-injection assembly and the required temperature for the fourth volume of temperature controlled fluid;
controlling the temperature of the fluid in the pre-injection assembly in response to the temperature difference; and
flowing the fourth volume of the temperature controlled fluid from the pre-injection assembly.

22. The method of operating a processing system as claimed in claim 20 further comprising keeping the temperature difference less than approximately five degrees Celsius.
